(19) United States
(12) Patent Application Publication
(10) Pub. No.: US 2006/0108402 A1
(43) Pub. Date: May 25, 2006

(54) Solder ball formation and transfer method

(75) Inventors: Richard Dewitt Crisp, Castro Valley, CA (US); Giles Humpston, San Jose, CA (US)

Correspondence Address: TESSERA;LERNER DAVID et al., 600 SOUTH AVENUE WEST, WESTFIELD, NJ, 07090, US

(73) Assignee: Tessera, Inc., San Jose, CA (US)

(21) Appl. No.: 10/993,962

(22) Filed: Nov. 19, 2004

(51) Int. Cl. B23K 31/02

(52) U.S. Cl. 228/248.1

(57) ABSTRACT

A method of forming and applying a solder mass comprised of depositing solder paste containing a carrier and a solder onto a first substrate, not wettable by said solder; reflowing the solder paste on the first substrate to cause the solder to coalesce into a solder mass; and transferring the solder mass from the first substrate to a second substrate.

### BACKGROUND OF THE INVENTION

The present invention relates to a method of solder sphere formation and specifically to methods of forming an array of satellite-free solder spheres for use in connection with chip package assemblies and the like.

It is well known in the surface mount technology art to mount components on one or both surfaces of a substrate using masses of solder in the shape of spheres or balls. For example, solder balls are commonly used as a means for attaching and interconnecting chip packages to printed circuit boards. It is therefore necessary to form an array of accurately dimensioned solder balls on a substrate, so as to accommodate the attachment of components to the substrate.

Various methods exist to create solder balls of different dimensions. Smaller solder balls, approximately 50 micrometers in diameter, are commonly formed by reflow of controlled thicknesses of metal that have been deposited at desired sites by an electroplating or vapor phase technique. Larger solder balls, approximately 300 micrometers in diameter, are usually produced as discrete spheres. The spheres are deposited onto a receiving surface by first placing excess quantities of solder spheres or the like onto a metal plate having openings which correspond to landings on the receiving substrate. After depositing an excess quantity of solder spheres onto the metal plate, the solder spheres will fall through each opening in the shape of spheres and onto the receiving substrate. Solder flux typically is applied to the receiving substrate to hold the balls in place after the metal plate and surplus spheres have been removed. Solder spheres are then reflowed to attach them securely to the wettable metal on the receiving substrate.

Processes for forming and depositing solder spheres of intermediate size ranging from approximately 50 micrometers to 300 micrometers, however, are not as accurate and present many problems. Forming spheres with intermediate dimensions require depositing a thickness of metal that is thicker than can be achieved at an economic rate by wet plating and vapor phase techniques. Furthermore, coalescing smaller solder spheres into an intermediate size is difficult to accomplish. Smaller solder spheres are more difficult to handle because they are light and move under the influence of static electricity. They therefore fail to remain in position when placed on a substrate. It is for this reason that single solder spheres smaller than 125 micrometers but larger than 50 micrometers are uncommon.

Several attempts have been made to create solder spheres of intermediate size. For example, in the process of screen printing, very fine solder spheres (smaller than 50 micrometers in diameter) are mixed with flux and the resulting paste is forced through a stencil, or apertures on a metal plate, to the substrate below. The solder paste is reflowed causing the finer solder spheres to coalesce to form a single larger sphere. However, screen printing has several drawbacks. Screen printing is limited by the size of the opening that can be reliably made in the stencil. Additionally, the process is further limited by the need for a minimum amount of metal between adjacent holes of the stencil to ensure that the stencil will survive the printing process. Indeed, screen printing solder paste at below 150 micrometers pitch requires advanced technology, but achieves only moderate yields.

Another method of achieving solder formation of an intermediate size involves the use of a syringe connected to a fine needle. The syringe dispenses solder paste to a desired location and in desired amounts using computer-controlled stages. Like screen printing, dispensing solder paste through a syringe presents several drawbacks. First, it is not possible to obtain consistent volumes of solder when the solder spheres are reflowed. This is due to the inability of the fine solder balls to successfully coalesce into a larger sphere. The remaining residues, commonly referred to as satellites, remain scattered across the solder paste. The satellites are mobile and prone to causing electrical shorts, mechanical interference to micro electro-mechanical system (“MEMS”) devices, and blocking all or part of the light path in photonics devices such as image sensors.

It is therefore desirable to find a cost-effective method of creating one or more accurately dimensioned solder spheres that are free of satellites.

### SUMMARY OF THE INVENTION

Preferred methods according to the present invention are designed to overcome the shortcomings associated with prior art methods of solder sphere formation by providing a method of easily producing solder spheres that are free from satellites of solder.

A method of forming and applying a solder mass in accordance with one aspect of this invention comprises depositing solder paste containing a carrier and a solder onto a first substrate not wettable by the solder, and reflowing the solder paste on the first substrate to thereby cause the solder to coalesce into the solder mass. Typically, the carrier wets the first substrate prior to conclusion of the reflowing. The method preferably includes the function steps of transferring the solder mass from the first substrate to a second substrate, which desirably includes a solder-wettable surface area.

The first substrate is preferably aligned with the second substrate prior to the transfer of the solder mass from the first substrate to the second substrate. In order to allow for accurate alignment of the solder mass on the first substrate with the desired location on the second substrate, the coefficient of thermal expansion of the first substrate is matched with the coefficient of thermal expansion of the second substrate. Alternatively, first and second substrates are aligned with each other at least in part by viewing the second substrate through the first substrate, which is optically transparent. Glass is preferably used as the optically transparent first substrate, and various types of glass may be used in accordance with this invention, such as frosted glass. In yet another alternative step of alignment, recesses on the surface of the first substrate may be used to define the locations of one or more solder spheres that will correspond to locations on the second substrate. Once the first and second substrates are aligned, the first substrate can then be removed away from the second substrate, so as to remove any residual solder paste and residual solder satellites.

The initial deposition of the solder paste may occur at more than one location on the first substrate so that more than one solder mass may be transferred to the second substrate simultaneously.

The amount of solder paste deposited onto the first substrate can be varied in order to obtain solder masses of different sizes preferably ranging from 50 micrometers to 300 micrometers in diameter.

Another method of forming and applying a solder mass in accordance with another aspect of this invention concerns reflowing the solder mass on the second substrate, preferably a pin, onto a third substrate.

A method of making a unit comprised of a solder mass on a first substrate not wettable by solder in accordance with another aspect of the invention is also disclosed. The method comprises depositing solder paste containing a carrier and a solder onto the first substrate and reflowing the solder paste on the first substrate to thereby cause the solder to coalesce into the solder mass.

In this method of making a unit, solder paste may also be deposited onto more than one location on the first substrate so as to allow formation of an array of solder masses. The deposition of the solder paste may be at locations which correspond to locations on a second substrate. Units formed in this manner can be handled, shipped and stored for later use in transferring the solder masses to a second substrate.

A further aspect of the invention provides unit comprising a first substrate and a plurality of masses of a solder disposed on a surface of said first substrate but not metallurgically bonded to said first substrate. Such a unit can be fabricated by the methods discussed above, or by other methods. Such a unit can be handled, shipped and stored as an article of commerce to provide a ready-made set of solder masses. A related aspect of the method includes applying such a unit to transfer solder balls to a second substrate.

These and other features and characteristics of the present invention will be apparent from the following detailed description of preferred embodiments, which should be read in light of the accompanying drawings in which corresponding reference numbers refer to corresponding parts throughout the several views.

### BRIEF DESCRIPTION OF THE DRAWINGS

FIGS. 1A-1D are sequential diagrammatic front cross-sectional views showing the sequence in fabricating and transferring a solder mass in accordance with an embodiment of the present invention;

FIG. 2A is a top view of an alternate intermediate glass substrate that may be used in accordance with other embodiments of the present invention;

FIG. 2B is a cross-sectional view of another alternate intermediate glass substrate that may be used in accordance with other embodiments of the present invention; and

FIGS. 3A-3E are sequential diagrammatic cross-sectional views showing the sequence in fabricating and transferring a solder mass in accordance with an alternative embodiment of the present invention.

### DETAILED DESCRIPTION

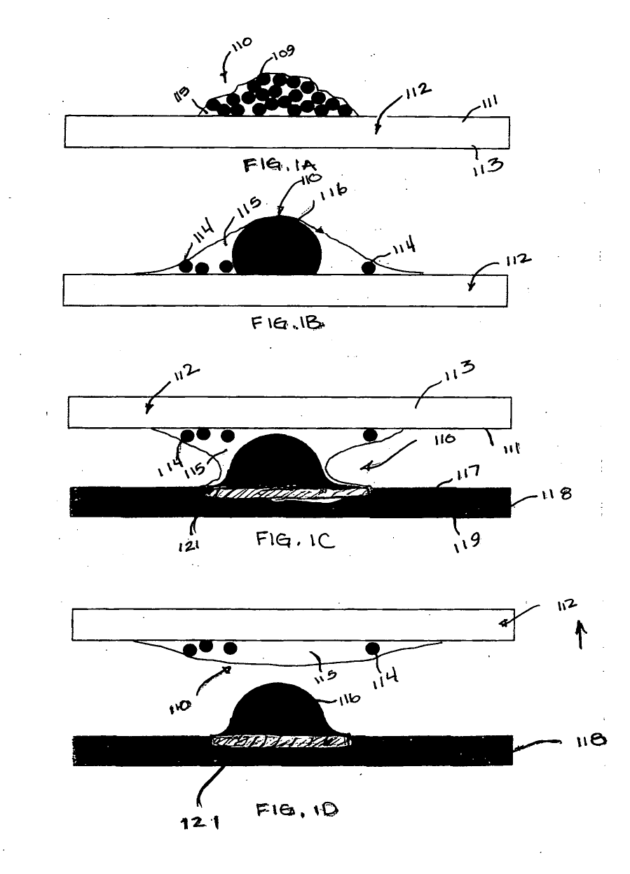

FIGS. 1A-1D illustrate a method of solder mass or ball formation in accordance with one embodiment of the present invention. Referring to FIG. 1A, there is shown a reusable or intermediate substrate 112 that is preferably not wettable by solder. The intermediate substrate has opposed first and second surfaces 111, 113 and is preferably used to facilitate the initial formation of a solder sphere of desired size. As will be explained in greater detail herein, the intermediate substrate 112 is preferably comprised of glass, such as borosilicate glass.

In a first step of the process, a predetermined amount of a source of solder is deposited onto the intermediate substrate 112. In a preferred embodiment, the source of solder is a commercially available solder paste that contains at least solder and a carrier, such as flux. As shown in FIG. 1A, solder paste 110 is deposited onto the intermediate substrate 112 using a known method of deposition such as screen printing, use of a syringe, or the like. The solder paste 110 contains small masses 109 of solder that are suspended in flux 115.

Because its ability to flow permits distribution of the solder paste, use of solder paste 110 to form solder spheres is desirable. Furthermore, solder paste 110 is unaffected by static charge, which can disrupt formation of a unified solder sphere. These factors aid in keeping the solder paste 110 in its original position on the intermediate substrate 112. Accordingly, it is possible to achieve accurate placement and transfer of a newly formed solder sphere when transferring the solder sphere from intermediate substrate 112 to a receiving substrate as discussed below.

Referring to FIG. 1B, once the solder paste 110 is deposited onto the intermediate substrate 112, the solder paste is heated or reflowed to formulate a solder sphere 116. Although the present invention is not limited by any theory of operation, it is believed that during reflow, the contact angle between the flux wetted to the intermediate substrate 112 and the small masses 109 of solder in surface tension force help to sweep the small masses 113 of solder toward the center of the dispensed solder paste 110. The majority of the solder found in the solder paste 110 coalesces to form a single large solder sphere 116. In some cases, however, not all of the solder is able to coalesce, thereby leaving behind residual satellites 114 of solder surrounding the solder sphere 116. In either event, the reflowed solder is allowed to cool. The flux 115 remains bonded to the intermediate substrate 112 so that although the solder sphere 116 and any remaining satellites 114 are not metallurgically bonded to the intermediate substrate 112 (since the intermediate substrate 112 is not wettable by solder), they will remain affixed to it by solidified flux residues. This helps to position the solder sphere 116 precisely at the center of the site on the intermediate substrate where the solder paste 110 was originally dispensed.

As shown in FIG. 1C, the receiving substrate 118 has opposed first and second sides 117, 119. Although the receiving substrate 118 is generally not wettable by solder, it preferably contains a contact pad or other feature 121 that is wettable by solder. The receiving substrate may be any element to which a solder sphere is to be applied as, for example, an unpackaged microelectronic element such as a semiconductor chip; a semiconductor wafer; a packaged microelectronic element; or a circuit board. The intermediate substrate 112 is preferably inverted and aligned with the receiving substrate 118 so that the first side 111 of the intermediate substrate 112 and the first side 117 of the receiving substrate 118 are facing one another. The intermediate substrate 112 is aligned with the receiving substrate 118 so that solder sphere 116 is then aligned directly on top of the contact pad 121. It should be appreciated that the position of the receiving substrate is not limited to the position shown in FIGS. 1C-1D (below the intermediate substrate). In this regard, the position of the receiving substrate will preferably determine where the intermediate substrate 112 needs to be positioned (i.e., above, below, to the left, to the right, or at an angle to the receiving substrate 118) in order to align the solder sphere 116 on the intermediate substrate 112 with the contact pad 121 on the receiving substrate 118. The substrates may be provided with fiducial marks which can be observed by a human observer or a machine vision system.

The preferable use of transparent glass as the intermediate substrate 112 can simplify the process of aligning and verifying that the solder sphere 116 has been accurately positioned on the receiving substrate 118. By looking through a transparent glass intermediate substrate, an individual is able to visually align the solder sphere 116 with the contact pad 121. In an automated process, a robotic vision system may be used to align the solder sphere 116 on the intermediate substrate 112 with the receiving substrate 118.

The use of glass as the intermediate substrate 112 is also preferred because its wide range of expansivities assists in accurate alignment of a solder sphere on a receiving substrate. Typically, solder spheres formed on an intermediate substrate are formed at locations that will correspond to locations, such as contact pads, on the receiving substrate. Because the solder sphere 116 is transferred to the receiving substrate 118 at the transfer temperature, and not at room temperature, the alignment of the solder sphere 116 with the contact pad 121 on the receiving substrate 118 must occur at the temperature of transfer. However, the coefficient of thermal expansion of certain types of glass closely parallels the coefficient of thermal expansion of silicon from room temperature to the reflow temperature of the solder (i.e., 20° C. to 300° C.), allowing silicon and glass to expand at the same rate. It is therefore possible for the position of the solder sphere 116 on a glass intermediate substrate to always correspond to a desired location on a receiving substrate comprised of silicon. Thus, when it is desired to deposit a solder sphere 116 onto a chip, wafer, or device comprised of silicon, the use of glass as the intermediate substrate permits accurate placement of the solder sphere onto a silicon receiving substrate.

Returning back to FIG. 1C, once the solder paste 110 containing the solder sphere 116 is aligned with contact pad 121 on the receiving substrate 118, the solder paste 110 is reflowed again to remelt the solder, as well as the flux 115 residues solidified in the solder paste 110 that bind the solder sphere 116 to the intermediate substrate 112. The second reflow process allows the solder sphere 116 to wet onto the contact pad 121 of the receiving substrate 118.

Referring to FIG. 1D, while the flux 115 is molten, the intermediate substrate 112 is then lifted away from the receiving substrate 118. Solder satellites 114 which may remain on the intermediate substrate 112 will be removed from the receiving substrate 118 by lifting the intermediate substrate 112 away from the receiving substrate 118. Such solder satellites 114 will remain trapped by the surface tension of the molten flux on the intermediate substrate 112 when it is pulled away. As a result, the solder sphere remains on the receiving substrate while remaining satellites 114 trapped in the flux 115 are removed. This process greatly reduces the amount of satellites 114 on the receiving substrate 118 by comparison to the number of satellites which would be formed on the second substrate at direct deposition of the solder paste on the second substrate.

The aforementioned steps describe the process of removing the intermediate substrate 112 away from the receiving substrate 118 when the flux is molten. In an alternative embodiment, the intermediate substrate 112 may also be lifted away from the receiving substrate 118 after the flux has solidified. One method contemplates the use of a mechanical means, such as a robotic arm, to lift the intermediate substrate 112. Another method contemplates the use of chemical means, such as a solvent for the flux to dissolve solidified flux residues that retain the solder sphere to the intermediate plate. Dissolution of the solidified flux residues eliminates the bond between the intermediate substrate 112 and the solidified flux, thereby allowing removal of the intermediate substrate 112 away from the receiving substrate 118.

After transfer of the solder balls to the second substrate, the second substrate can be mounted to a further substrate (not shown) as, for example, a printed circuit board using the solder ball to bond contact pads 121 of the second substrate to a contact pad (not shown) of the further substrate.

Because solder spheres, when molten, will not wet to a glass substrate, the process may be performed several times on the same receiving substrate 112, such that spheres of different or similar dimensions and/or compositions may populate the same receiving substrate. At the conclusion of the process, the flux residues and solder satellites 114 may be removed from the intermediate substrate 112 using appropriate solvents. The intermediate substrate 112 can then be cleaned and ready for reuse.

The size of the final solder sphere 116 at each desired location on the receiving substrate 118 directly corresponds to the amount of solder paste 110 originally dispensed onto the intermediate substrate 112. One may, therefore, obtain solder spheres of different sizes by varying the amount of solder paste applied. Determining the amount of solder paste necessary to achieve solder spheres of different sizes will depend, however, on the percentage of solder originally found in the solder paste.

FIGS. 1A-1D depict the formation and application of only one solder ball. However, the process most typically is performed so as to form and transfer numerous solder spheres simultaneously. Thus, multiple deposits of solder paste 110 may be deposited onto the intermediate substrate, so that more than one solder sphere is formed at one time. The multiple deposits of solder paste may be applied in an array of locations on the intermediate substrate corresponding to the array of contact pads or other solder-wettable features on the second substrate. Thus, after reflowing to form solder spheres, all of the spheres can be aligned with respective pads simultaneously by aligning the intermediate substrate with the second substrate.

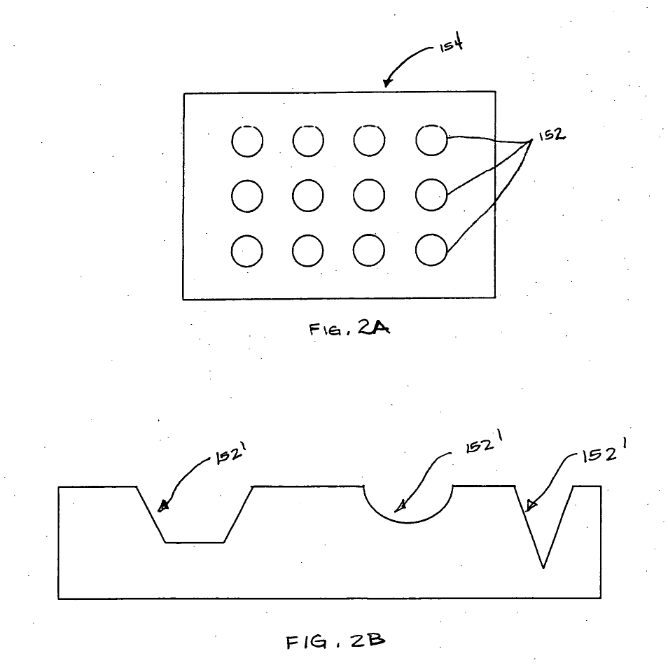

In the alternative embodiment of an intermediate substrate shown in FIG. 2A, several etched pits 152 are provided on a glass intermediate substrate 154 to allow for the formation of more than one solder sphere on the intermediate substrate 154, and to increase accurate placement of a solder paste onto the intermediate substrate 112. As shown in FIG. 2B, the etched pits 152′ may be created in a variety of shapes and sizes. FIG. 2B illustrates several recesses of different shapes and sizes in the same intermediate substrate. In practice, any of these shapes (and other shapes) can be used, but typically all of the recesses in a given substrate would be substantially identical. The etched pits 152 and 152′ are recesses in the surface of the glass intermediate substrate 112 which can be formed using wet etching. The etched pits 152 are disposed in the array corresponding to the desired placement of the solder spheres, i.e., in an array corresponding to the array of contact pads or other features on a chip or other substrate. This is beneficial because the flux 115 in the solder paste 110 is wetted onto the surface of the intermediate surface 112 allowing surface forces to pull the puddle of dispensed paste toward the center of the etched pits 152, thereby centering the masses of paste in the locations of the array. Additionally, the recesses may be filled with solder paste by wiping excess material across the face of the plate. The solder in the recesses will be in the form of a molten solder puddle. Thus, the incorporation of such etched pits 152 aids in increasing the positional accuracy of a final solder sphere.

It should be further appreciated that once the solder paste 110 has been reflowed and solidified into one or more solder spheres on the intermediate substrate, the combination of the intermediate substrate with the newly solidified solder sphere or spheres (See FIG. 1B) may be stored away as a unit, and subsequent steps performed at a later time when it is desired to finally transfer the solder sphere 116 to a receiving substrate 118. Typically, such a unit includes an array of solder spheres. Such units may be especially useful when it is desired to keep arrays of solder spheres in storage that will correspond to one or more contact pads or other conductive features on a receiving substrate. Units with the intermediate substrate and solder spheres attached thereto by solidified flux can be fabricated in mass production and used in the same plant, or in a separate plant to transfer the solder spheres to the second substrate. The plant that performs the transfer to the second substrate need not have the equipment required to dispense solder paste.

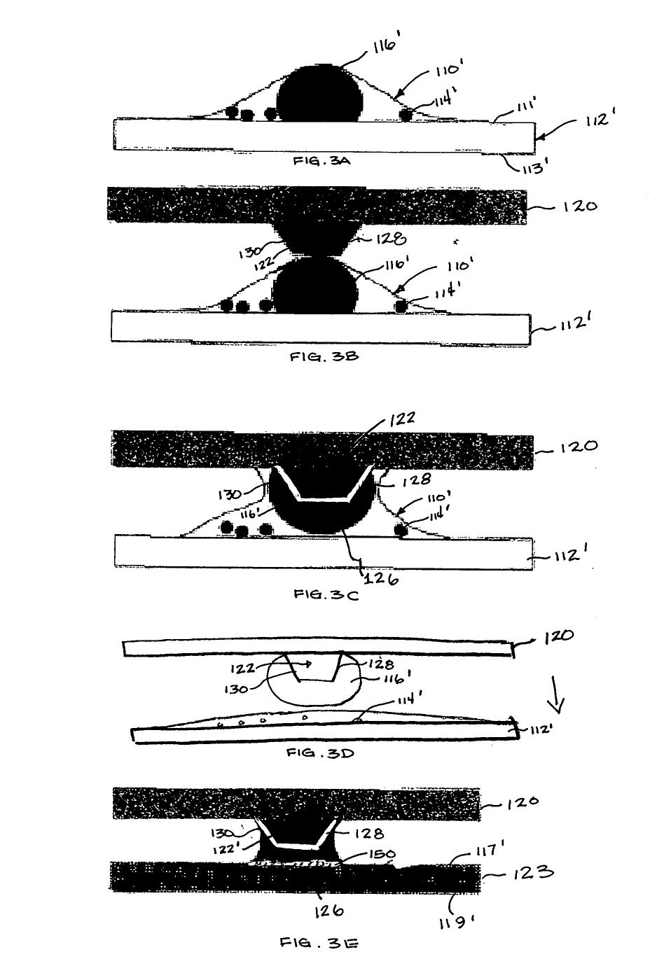

Referring to FIGS. 3A-3E, an alternative method of solder formation and transfer, in accordance with the present invention, is shown. As shown in FIG. 3A, a solder sphere 116′ is formed on an intermediate surface 112′, preferably glass. The intermediate surface 112′ has opposed first and second sides, 111′ and 113′. As previously disclosed herein, solder paste 110′ is deposited on the intermediate substrate 112′ and reflowed to form a large solder sphere 116′.

Referring to FIG. 3B, a first receiving substrate 120 preferably comprising a pin 122, such as a Socketstrate® pin, is aligned with the solder sphere 116′ found on the intermediate substrate 112′. (Socketstrate® is a trademark owned by Tessera, Inc. and disclosed in pending U.S. Application No. 60/583,108 filed on Jun. 25, 2004; U.S. Application No. 60/583,109 filed Jun. 25, 2004; and an application entitled, “Microelectronic Packages and Method Therefor,” filed on Jun. 25, 2004, which are incorporated herein by reference.)

The pin 122 has a pin head 126, a first angled sidewall 128 and a second angled sidewall 130. It is possible to achieve close pitches of solder components by transferring the solder sphere 116′ directly onto the pin 122 and then aligning the pin with a desired object located on a second receiving substrate 123.

Referring to FIG. 3C, the pin 122 is placed into the solder sphere 116′, such that the head 126, and first and second angled walls 128, 130 are enveloped by the solder sphere 116′. Thereafter, the solder paste 110 is reflowed and the solder sphere 116′ is able to wet to the pin 122, as well as dewet from the intermediate surface 112′.

Referring to FIG. 3D, the intermediate substrate 112′ is pulled away from the first receiving substrate 120, or pin 122. When the intermediate substrate 112′ is removed, residual satellites 114′ of solder that may remain are removed, but the solder sphere 116′ remains on the pin.

Referring to FIG. 3E, there is a second receiving substrate 123, such as a silicon chip or a printed circuit board, that has opposed first and second sides 117′ and 119′. The pin 122, which carries the solder sphere 116′, is placed onto the first side 117′ of the second receiving substrate 123. The solder sphere 116′ is then again reflowed to attach the pin 122 to a land 150 on the receiving substrate 118′.

Although the invention herein has been described with reference to particular embodiments and preferred dimensions or ranges of measurements, it is to be understood that these embodiments are merely illustrative of the principles and applications of the present invention. Additionally, it is to be appreciated that the present invention may take on various alternative orientations. It is therefore to be understood that numerous modifications may be made to the illustrative embodiments and that other arrangements may be devised without departing from the spirit and scope of the present invention as defined by the appended claims.

1. A method of forming and applying a solder mass comprising:
a. depositing solder paste containing a carrier and a solder onto a first substrate, not wettable by said solder;
b. reflowing said solder paste on said first substrate to thereby cause said solder to coalesce into a solder mass; and
c. transferring said solder mass from said first substrate to a second substrate.

2. The method according to claim 1, wherein said carrier wets said first substrate prior to conclusion of said reflowing.

3. A method according to claim 2 wherein said transferring step includes transferring said solder mass to a solder-wettable feature on said second substrate.

4. The method according to claim 3, further including aligning said first substrate with said second substrate prior to said transferring of said solder mass.

5. A method according to claim 4, wherein said aligning step includes aligning said first and second substrates at least in part by viewing said second substrate through said first substrate, wherein said first substrate is optically transparent.

6. The method according to claim 1, further including removing said first substrate away from said second substrate so as to remove any residual solder paste or residual solder satellites.

7. The method according to claim 1, wherein said solder paste is deposited at more than one location on said first substrate, and more than one solder mass is transferred to said second substrate simultaneously.

8. A method according to claim 1, wherein the coefficient of thermal expansion of the first substrate is matched with the coefficient of thermal expansion of the second substrate.

9. A method according to claim 1, wherein said deposition and reflow steps include using a glass as said first substrate.

10. A method according to claim 9, wherein said glass is frosted glass.

11. A method according to claim 1, wherein said first substrate has recesses on a surface of said substrate to assist in defining the location of the solder spheres.

12. A method according to claim 11, wherein said recesses are comprised of different shapes and sizes.

13. A method according to claim 1, further comprising varying the amount of said solder paste deposited onto said first substrate in order to obtain different sizes of solder masses.

13. A method according to claim 1, wherein said depositing and reflowing steps are performed so as to create solder spheres in the size range of 50 micrometers to 300 micrometers in diameter.

14. The method according to claim 1, further comprising reflowing said solder mass on said second substrate onto a third substrate.

15. The method according to claim 1, wherein said second substrate includes a pin.

16. A process of making a unit comprised of a solder mass on a substrate not wettable by solder, said process comprising:
a. depositing solder paste containing a carrier and a solder onto said first substrate; and
b. reflowing said solder paste on said first substrate to thereby cause said solder to coalesce into said solder mass.

17. The method according to claim 16, wherein said solder paste is deposited at more than one location on said first substrate so as to form an array of solder masses on said substrate.

18. The method according to claim 17, wherein said substrate is a first substrate and said array of solder masses corresponds to locations on a second substrate.

18. The process according to claim 16, further comprising packaging said unit.

19. The process according to claim 16, further comprising storing said unit.

20. The process according to claim 16, further comprising shipping said unit to a different location.

21. A unit comprising a first substrate and a plurality of masses of a solder disposed on a surface of said first substrate but not metallurgically bonded to said first substrate.

22. A unit as claimed in claim 21 wherein said first substrate includes glass defining said surface.

23. A unit as claimed in claim 22 wherein said first substrate is formed entirely from glass.

24. A unit as claimed in claim 21 further comprising a flux contacting and adhering to said solder masses and said first substrate so that said flux holds said solder masses to said first substrate.

25. A unit as claimed in claim 21 wherein said masses of solder are disposed in an array.

26. A method of applying solder masses comprising aligning a unit as claimed in claim 21 with a second substrate having solder-wettable features thereon so that said masses of solder are aligned with said solder-wettable features, reflowing said solder in said masses so that said solder wets said features, and then removing said first substrate of said unit away from said second substrate.
